(19) United States
(12) Patent Application Publication
(10) Pub. No.: US 2011/0012267 A1
(43) Pub. Date: Jan. 20, 2011

(54) SEMICONDUCTOR INTEGRATED DEVICE HAVING A CONTACT STRUCTURE, AND CORRESPONDING MANUFACTURING PROCESS

(75) Inventors: Riccardo Depetro, Domodossola (VB) (IT); Stefano Manzini, Novara (IT)

Correspondence Address: STMicroelectronics Inc.;c/o WOLF, GREENFIELD & SACKS, P.C., 600 Atlantic Avenue, BOSTON, MA, 02210-2206, US

(73) Assignee: STMicroelectronics S.r.l., Agrate Brianza (MI) (IT)

(21) Appl. No.: 12/836,976

(22) Filed: Jul. 15, 2010

(30) Foreign Application Priority Data
Jul. 17, 2009 (IT) TO2009A000536

(51) Int. Cl. H01L 23/48; H01L 21/768

(52) U.S. Cl. 257/773; 438/612; 257/E23.011; 257/E21.585

(57) ABSTRACT

An integrated device, including: a first conductive region; a second conductive region set at a distance from the first conductive region; an etch-stop layer, made of a first dielectric material, at least partially overlapped on the first and second conductive regions; an insulating layer, made of a second dielectric material, different from the first, overlapped on the first and second conductive regions and on the etch-stop layer; at least one through opening extending through the insulating layer and the etch-stop layer; and a barrier layer, made of a third dielectric material, different from the first, set between the first conductive region and the etch-stop layer and between the second conductive region and the etch-stop layer.

### CROSS REFERENCE TO RELATED APPLICATIONS

This application claims the priority benefit of Italian patent application number TO2009A000536, filed on Jul. 17, 2009, entitled “SEMICONDUCTOR INTEGRATED DEVICE HAVING A CONTACT STRUCTURE, AND CORRESPONDING MANUFACTURING PROCESS,” which is hereby incorporated by reference to the maximum extent allowable by law.

### BACKGROUND OF THE INVENTION

1. Field of the Invention

The present invention relates to a semiconductor integrated device having a contact structure and to the corresponding manufacturing process.

2. Discussion of the Related Art

To provide integrated electronic devices, in particular ones designed to operate at high voltage (indicatively higher than 5 V), such as, for example, high-voltage MOSFETs, it is known to form the drain region of the transistor itself at a distance from the gate region. In some cases, if the operating voltages are very high, it may be expedient to form between the drain region and the gate region an oxide layer, for example a thermally grown oxide, or a field oxide, or a shallow-trench-insulation (STI) technique or other techniques may be used.

FIG. 1 shows, in cross-sectional view, a portion of a MOSFET device comprising a substrate 1, for example, made of silicon of a P type; an epitaxial layer 2, for example made of silicon with N− doping, grown on the substrate 1; an insulating region 3, for example, made of silicon oxide, provided in the epitaxial layer 2 by means of the STI technique; a gate region 4, comprising a conductive region 5, for example made of doped polysilicon, and an insulating gate region 6, for example made of silicon oxide, designed to insulate electrically the conductive region 5 from the epitaxial layer 2; a drain region 8, formed in the epitaxial layer 2 alongside the gate region 4 and at a distance therefrom, and separated from the gate region 4 by the insulating region 3; and a protection region 10, for example made of silicon oxide, having a thickness of between 0.5 μm and 2 μm, designed to protect and insulate the gate region 4 and the drain region 8 from the outside environment.

FIG. 1 moreover shows a through opening 12, provided in the protection region 10, partially on the drain region 8, and designed to be used to provide an electrical contact (not shown) of the drain region 8. On account of possible errors of alignment, the mask used for the formation of the through opening 12 may be misaligned in regard to the boundary portion between the drain region 8 and the insulating region 3; in particular, it can extend partially over the insulating region 3. During a step of etching of the protection region 10 to provide the through opening 12, on account of the process tolerances there is noted an etch also of the insulating region 3 in a boundary portion 14 between the latter and the drain region 8. Said etch, which may extend inside the insulating region 3 up to approximately 0.5 μm, jeopardizes the functions of said insulating region 3.

In order to solve said problem a technique of opening contacts has been proposed known as “borderless-contact opening”, and the respective contacts provided are known as “borderless contacts”. As is shown in FIG. 2, said solution envisages, during the steps of manufacturing of the device, the deposition of an etch-stop layer 16, generally made of silicon nitride or silicon oxynitride. In this way, by means of successive selective etches of the protection region 10 and of the etch-stop layer 16, it is possible to provide the through opening 12 preventing any damage from overetching of the insulating region 3.

However, in the case where the through opening 12 is formed completely on the drain region 8, the etch-stop layer 16 will find itself partially in direct contact with the drain region 8 and, at the same time, partially in direct contact also with the gate region 4. Said situation is shown in FIG. 3.

In this case, during use of the MOSFET device, in particular in the case of high biasing voltages (indicatively higher than 5 V), there can occur an injection of charge from the drain region 8 to the etch-stop layer 16. Said behavior is known and described, for example, in the publication by S. Manzini, “Electronic processes in silicon nitride”, Journal of Applied Physics, vol. 62, pp. 3178-3284, 1987.

On account of the type of electrical conductivity of the silicon nitride (of a Poole-Frenkel type), and on account of the behavior of the silicon nitride as trapping insulator, the charge injected in the etch-stop layer 16 remains trapped therein also at the end of use of the MOSFET device.

The effect described is more evident during test of reverse-biasing operation at a high temperature, during which a high voltage is applied between the drain region 8 and the gate region 4, favoring charge injection in the etch-stop layer 16. The trapped charge is not removed and generates a depletion region 18 in the epitaxial layer 2, which degrades the performance of the MOSFET device. Affected in particular by degradation are the electrical characteristics of the MOSFET device, such as, for example, the value of resistance in the ON state R_{ON}, the value of transconductance, the value of BVdss (breakdown voltage of the drain terminal with the gate terminal at the ground voltage), etc.

### SUMMARY OF THE INVENTION

An aim of the present invention is consequently to provide a semiconductor integrated device having a contact structure and the corresponding manufacturing process that will enable the above drawbacks to be overcome.

According to at least one embodiment there is provided a semiconductor integrated device having a contact structure comprising: a first conductive region; a second conductive region arranged at a distance from the first conductive region; an etch-stop layer, made of a first dielectric material, at least partially overlapped on said first and second conductive regions; an insulating layer, made of a second dielectric material, different from the first, overlapped on said first and second conductive regions and on said etch-stop layer; and at least one through opening extending through said insulating layer and said etch-stop layer, and a barrier layer, made of a third dielectric material, different from the first, arranged between the first conductive region and the etch-stop layer and between the second conductive region and the etch-stop layer.

According to at least one embodiment, the device comprises a switching device in MOS technology, wherein the first conductive region is a control terminal, and the second conductive region is a conduction terminal.

According to at least one embodiment, the device further comprises a contact structure formed in said through opening, said contact structure comprising a layer of conductive material configured to electrically contact said second conduction region.

According to at least one embodiment, the etch-stop layer is made of silicon nitride or silicon oxynitride.

According to at least one embodiment, the barrier layer is made of silicon oxide.

According to at least one embodiment, the barrier layer has a thickness of between 10 nm and 100 nm.

According to at least one embodiment, the integrated device comprises a semiconductor body, wherein said conduction terminal is formed inside the substrate, said control terminal is arranged above the semiconductor body, laterally and at a distance from the conduction terminal, and a dielectric insulating region extends between the control terminal and the conduction terminal.

According to at least one embodiment, there is provided a process for manufacturing a contact structure for an integrated device, comprising the steps of: forming a first conductive region; forming a second conductive region at a distance from the first conductive region; forming, at least partially overlapped on said first and second conductive regions, an etch-stop layer, made of a first dielectric material; forming an insulating layer, made of a second dielectric material different from the first, overlapped on said first and second conductive regions and on said etch-stop layer; and removing selective portions of said insulating layer and of said etch-stop layer, to form at least one through opening, wherein, before said step of forming the etch-stop layer, forming a barrier layer, made of a third dielectric material, different from the first.

According to at least one embodiment, the process further comprises, immediately after said step of removal of selective portions of said insulating layer and of said etch-stop layer, the step of removal of a selective portion of said barrier layer.

According to at least one embodiment, the third dielectric material is silicon oxide of a thickness of between 10 nm and 100 nm.

According to at least one embodiment, the first dielectric material is made of silicon nitride or silicon oxynitride.

According to at least one embodiment, the process further comprises providing a semiconductor body; wherein forming a first conductive region comprises providing a control terminal of a switching device in MOS technology on the semiconductor body, and forming a second conductive region comprises forming a conduction terminal inside the semiconductor body, and the step of forming the barrier layer comprises depositing the third dielectric material on the semiconductor body.

According to at least one embodiment, the process further comprises forming a dielectric insulating region in the semiconductor body between the control terminal and the conduction terminal.

According to at least one embodiment, the process further comprises, after the step of forming at least one through opening, the step of depositing conductive material in said through opening so as to form a contact structure in direct electrical contact with said second conductive region.

### BRIEF DESCRIPTION OF THE DRAWINGS

For a better understanding of the present invention, a preferred embodiment thereof is now described, purely by way of non-limiting example and with reference to the attached drawings, wherein:

FIGS. 1 and 2 show respective embodiments of a known type of an integrated device comprising respective contact structures;

FIG. 3 shows the integrated device of FIG. 2 in an operative condition;

FIG. 4 shows a cross-sectional view of an integrated device comprising a contact structure according to one embodiment of the present invention; and

FIGS. 5-12 show cross-sectional views of the integrated device of FIG. 4 according to successive steps of a process for manufacturing said integrated device.

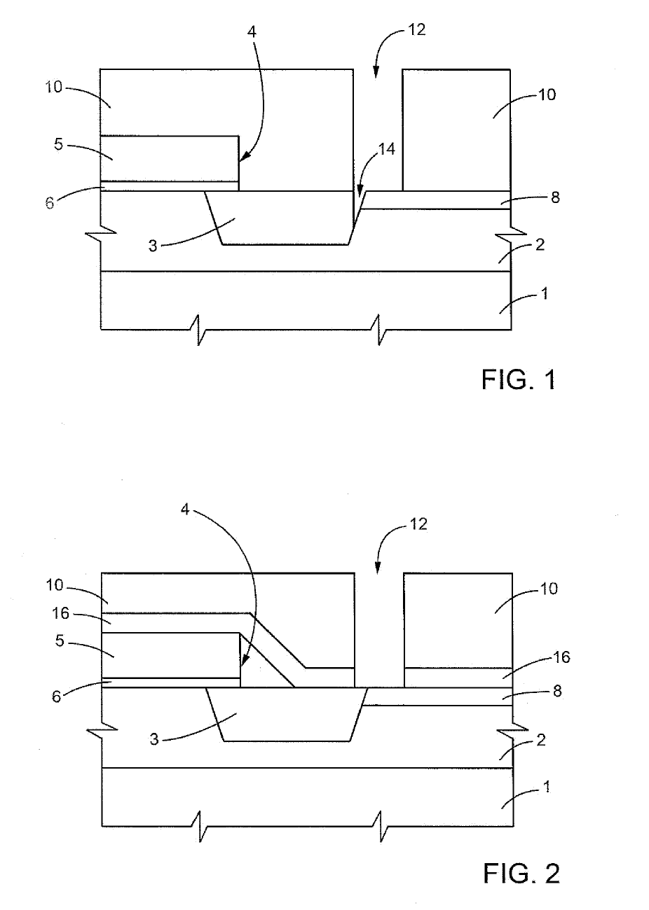

### DETAILED DESCRIPTION

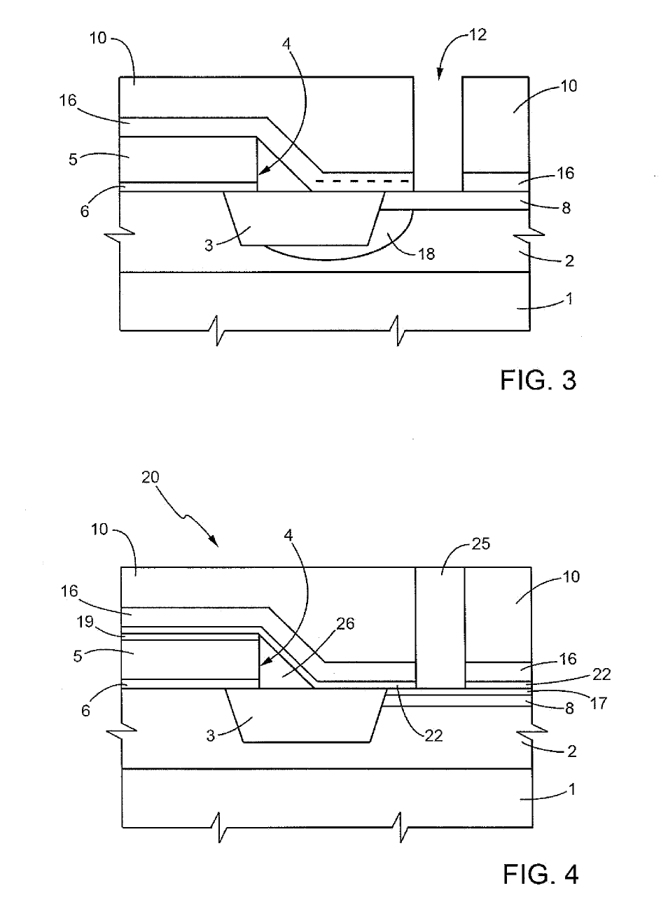

FIG. 4 shows a cross-sectional view of a portion of an electronic device 20, of an integrated type, in particular a MOSFET device configured to be used at high voltages, for example higher than 5 V. Elements of the electronic device 20 of FIG. 4 that are common to the MOSFET device shown in FIG. 3 are not described further and are designated by the same reference numbers.

In particular, the electronic device 20 of FIG. 4 has a barrier region 22, preferably made of dielectric material, for example silicon oxide (SiO₂), arranged between the epitaxial layer 2 and the etch-stop layer 16.

FIG. 4 moreover shows a drain-contact region 17 and a gate-contact region 19, made of metal silicide, aligned to the respective drain region 8 and gate region 4 and designed to favor an electrical contact between the drain region 8 and gate region 4 and respective conductive plugs (only one conductive plug 25, connected to the drain region 8, is shown in the figure).

The barrier region 22 is designed to interrupt the ohmic contact between the drain-contact region 17 and the etch-stop layer 16. The barrier region 22 provides in fact a potential barrier designed to confine the charges inside the epitaxial layer 2, limiting or preventing the flow of charges towards the etch-stop layer 16 during use of the electronic device 20 and in particular during test of reverse-biasing operation at high temperature. In theory, the charges present in the epitaxial layer 2 continue to have a certain likelihood of passing by the tunnel effect through the potential barrier provided by the barrier region 22. However, said likelihood decreases to irrelevant values for a barrier region having a thickness greater than 15 nm. A barrier region having a thickness of between 20 nm and 300 nm is sufficient for said purpose.

The use of said barrier region 22 also satisfies the purposes of the borderless-contact-opening process. In fact, after selective removal of the protection region 10 and the etch-stop layer 16, it is possible to proceed with selective removal of the thin barrier region 22. Given the small thickness of the barrier region 22, in order to ensure complete removal of the latter in the portion of the electronic device 20 in which it is desired to provide the through opening (in FIG. 4 said through opening is shown filled with conductive material to form the conductive plug 25), it is advantageous to define a step of etching of the barrier region 22 that will enable removal of a percentage comprised between 120% and 150% of the effective thickness of the barrier region 22. In this way, a complete removal of the portion of barrier region 22 is guaranteed, and at the same time the insulating region 3 is not damaged significantly in the case where the opening for the conductive plug 25 is partially provided on the insulating region 3.

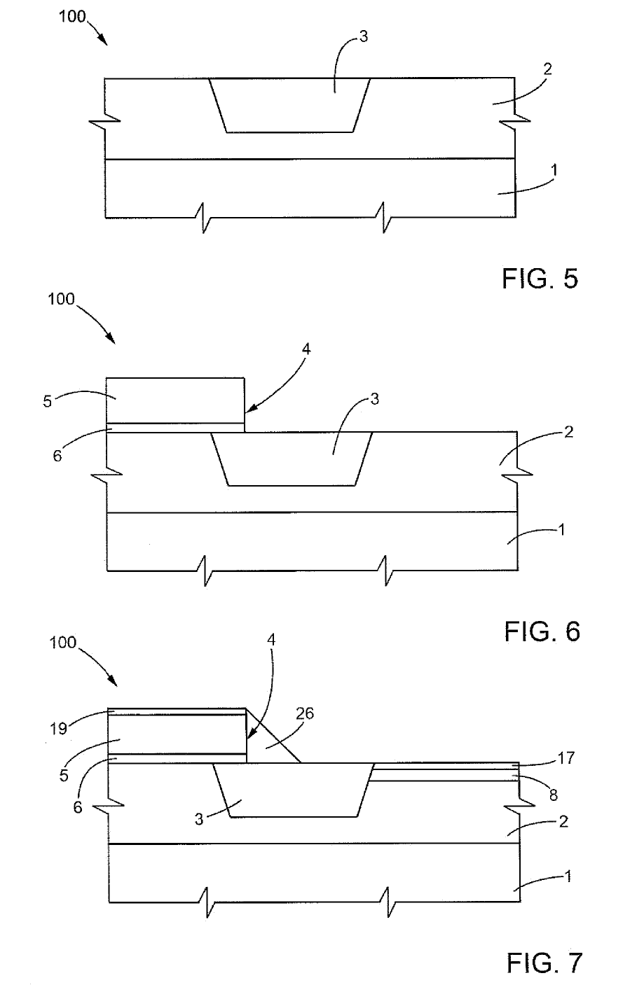

FIGS. 5-12 show successive steps of opening of a borderless contact according to one embodiment of the present invention, and in particular with non-limiting reference to the electronic device 20 of FIG. 4.

In the first place (FIG. 5), a wafer 100 is provided comprising a semiconductor substrate 1, for example, made of silicon of a P type. Then, grown on the substrate 1 is an epitaxial layer 2, for example of lightly doped silicon, of an N− type. An insulating region 3 is next formed in the epitaxial layer 2. The insulating region 3 can be formed by digging portions of epitaxial layer 2 by means of etching techniques of a known type and then filling said portions with silicon oxide or else by means of the STI technique, or by means of silicon oxide grown thermally, or using some other technique.

Then (FIG. 6), a first insulating layer is formed on the wafer 100, for example by growing silicon oxide (SiO₂), having a thickness of between 3 nm and 100 nm, preferably 7 nm, and is selectively removed to form the insulating gate region 6. Next, a conductive layer is deposited on the wafer 100, for example a layer of doped polysilicon of an N type, and is then selectively removed to form the conductive region 5 superimposed on the insulating gate region 6. As has been said, the insulating gate region 6 and the conductive region 5 provide the gate region 4 of the electronic device 20.

Next (FIG. 7), by means of a first ion implantation of dopant species of an N type, for example arsenic (As) or phosphorus (P), lightly doped (N−) drain and source regions are formed (only the drain region 8 is visible in FIG. 6).

Next, a second insulating layer, for example as layer of silicon oxide or silicon nitride having a thickness of between 100 nm and 500 nm, is deposited on the wafer 100 by means of LPCVD or PECVD technique, and subsequently removed via anisotropic dry etching so as to form spacers 26, alongside the gate region 4. Then, a second ion implantation of dopant species of an N type enables provision of heavily doped drain and source regions, of an N+ type.

It is possible in this step to form silicide regions, self-aligned to the drain region 8, the gate region 4, and the source region (the latter is not shown in the figure). For this purpose, formed on the wafer 100 is a conductive layer (not shown), for example a layer of metal deposited by the sputtering technique, preferably titanium sputtering.

A subsequent thermal process, for example a step of rapid thermal annealing (RTA) at a temperature comprised between 700° C. and 1000° C., preferably 900° C., for approximately one minute, favors formation of silicide in the regions of direct contact between the deposited conductive layer and the epitaxial layer 2 to form drain-contact regions 17 and gate-contact regions 19. Next, the conductive layer is etched, for example using a solution of HNO₃, to remove it from the wafer 100 except in the regions where the silicide is formed. Etching with nitric acid is in fact selective in regard to silicide, which is not removed.

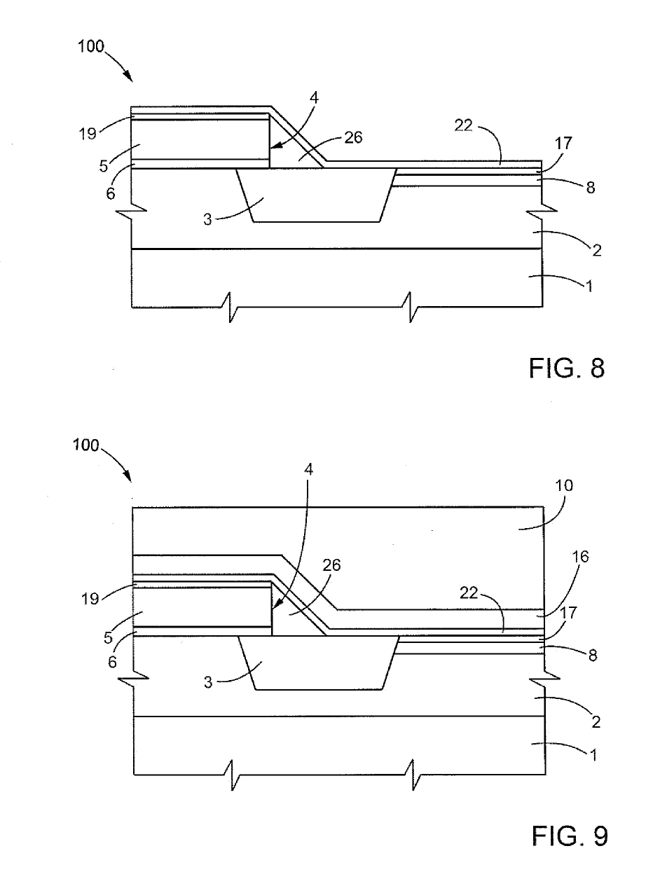

Next (FIG. 8), a layer of dielectric material, for example silicon oxide, is deposited to form the barrier region 22. In greater detail, the barrier region 22 can be formed by depositing, in a known way, silicon oxide.

Then (FIG. 9), formed on the wafer 100 is the etch-stop layer 16, for example made of dielectric material, more precisely silicon nitride or silicon oxynitride, having a thickness of between 10 nm and 200 nm, preferably 20 nm. The etch-stop layer 16 can be formed via known techniques of low-temperature deposition.

The use of silicon nitride or silicon oxynitride to form the etch-stop layer 16 affords the advantage of a high selectivity during the subsequent steps of etching to provide a through opening in which the conductive plug 25 is to be formed.

Next, the protection region 10 is formed on the wafer 100, for example by depositing silicon oxide via the PECVD or LPCVD technique, having a thickness of between 0.5 μm and 2.0 μm, preferably 0.8 μm. Alternatively, the protection region 10 can comprise non-doped glasses, or else phosphosilicate glass (PSG), or boron-phosphosilicate glass (BPSG). Then, the protection region 10 is planarized by means of chemical-mechanical polishing (CMP).

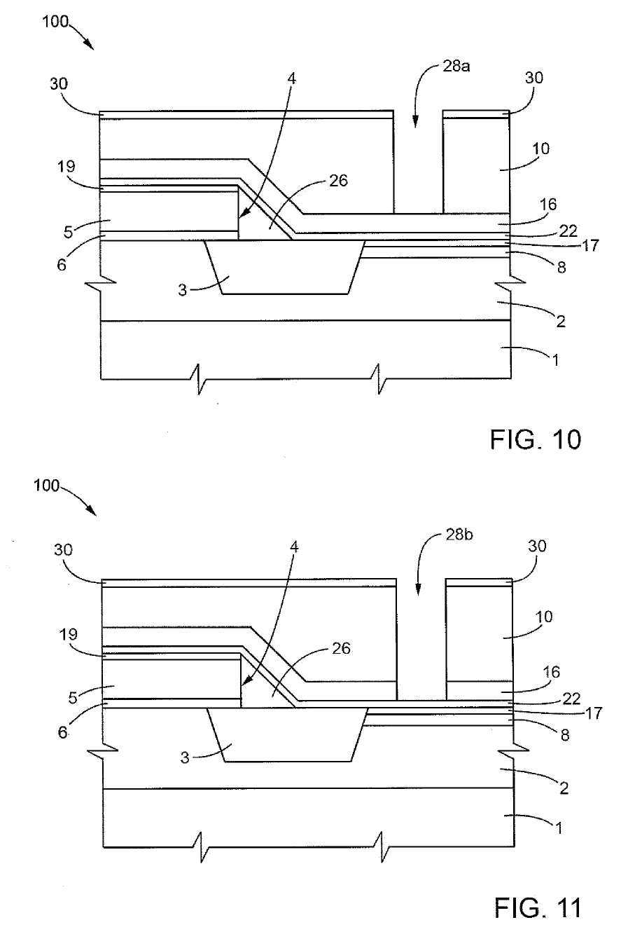

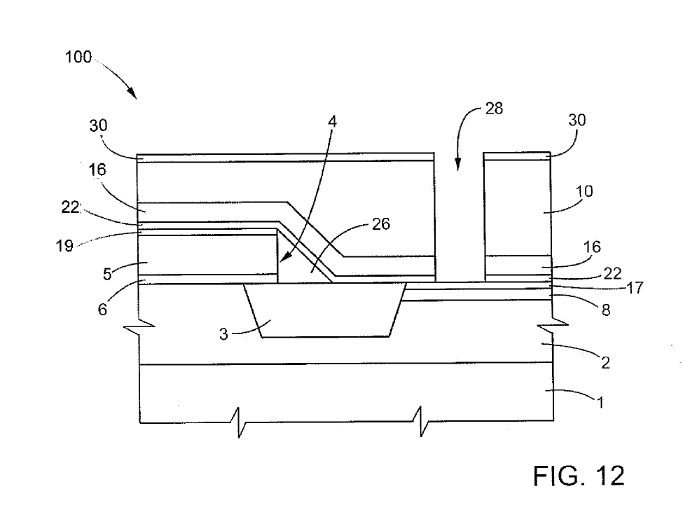

Next (FIGS. 10-12), the protection region 10, the etch-stop layer 16 and the barrier region 22 are selectively etched to form a through opening 28 (shown in FIG. 12).

In greater detail (FIG. 10), after providing an appropriate mask 30 on the wafer 10 (for example, a photoresist mask) a first etching step is performed, for example a reactive dry etch (RIE) using a mixture of CHF₃ and O₂. In this way, a portion of the protection region 10 is selectively removed to form a first opening 28a that exposes a portion of the etch-stop layer 16. Etching with CHF₃ and O₂ is in fact interrupted when the etch-stop layer 16 is reached since, as is known, silicon nitride or silicon oxynitride does not react with the mixture of CHF₃ and O₂.

It is evident that it is possible to use a different type of etching (for example wet etching) and/or different reagents in liquid or gaseous form provided that they are suited to remove selectively the protection region 10 and not the etch-stop layer 16.

Then (FIG. 11), using the same mask 30 previously provided for etching the protection region 10, the portion of the etch-stop layer 16 previously exposed is removed to form a second opening 28b that exposes a portion of the barrier region 22. For this purpose, a dry RIE can be carried out using CHF₃ for removing selectively the etch-stop layer 16, made of silicon nitride or silicon oxynitride, and not the barrier region 22, made of silicon oxide. In a way similar to what has been seen with reference to the preceding FIG. 10, also in this case it is possible to use a different type of etching (for example, wet etching) and/or different reagents in liquid or gaseous form provided that they are able to remove selectively the etch-stop layer 16 and not the barrier region 22.

Then (FIG. 12), a third etching step enables removal of the portion of the barrier region 22 exposed by means of the previous etch, thus exposing the drain-contact region 17 and providing the through opening 28.

This etch can be performed by means of a dry RIE process, using a mixture of CHF₃ and O₂ and calibrating the etch in such a way as to remove a thickness of the barrier layer 22 comprised approximately between 120% and 150% of the effective thickness of the barrier layer 22. In this way, it is possible to guarantee a complete exposure of the portion of the underlying drain-contact region 17 and a non-significant etching of the insulating region 3 in the case of partial misalignment of the through opening 28 with respect to the drain-contact region 17.

Finally, the mask 30 is removed, and the conductive plug 25 is formed inside the through opening 28, for example by depositing conductive material, e.g., tungsten, by means of chemical vapor deposition (CVD), up to complete filling of the through opening 28. A subsequent step of polishing, for example CMP, enables polishing of the wafer 100 to remove portions of conductive material outside the through opening 28.

Subsequent steps of provision of metal contacts on the wafer 100 for contacting the conductive plug 25 are not shown.

In this way, the electronic device 20 of FIG. 4 is obtained, comprising contact openings of a borderless type (just one contact is shown in the figure), which, in use, is free from the drawbacks described regarding the accumulation of charges in the etch-stop layer 16 with consequent generation of an underlying depletion area.

From an examination of the characteristics of embodiment of the present invention, the advantages that it affords are evident.

In particular, the barrier region 22, provided under the etch-stop layer 16, has the function, in use, of preventing an ohmic contact between the drain region 8 and the etch-stop layer 16, considerably limiting the accumulation of charges in the etch-stop layer 16.

At the same time, the advantages of the borderless-contact-opening technique are achieved, since it is possible to provide contact structures without damaging the underlying regions or the layers, even in the event of non-correct alignment of the mask/masks used for opening said contact structures. In fact, in the case of misalignment, a possible insulating region 3, made of silicon oxide, could be etched at the most for just a few nanometres (generally approximately 10-12 nm), without jeopardizing the functions thereof.

Finally, it is clear that modifications and variations may be made to what has been described and illustrated herein, without thereby departing from the sphere of protection of the present invention, as defined in the annexed claims.

In particular, even though the description makes explicit reference to a MOSFET for high-voltage use, the process described for providing borderless contacts can be applied to any integrated device, such as, for example, bipolar transistors, resistors, and FETs, in which it is desired to provide borderless contacts without the disadvantages described with reference to the known art, in particular with reference to FIG. 3. In addition, even though the description refers to a contact structure of a drain region, it is evident that said contact structure is suited to provide a contact of any conductive region of any integrated device, for example of a source region or gate region of a transistor.

In addition, the structure of the electronic device 20 can be different from the one shown in FIG. 4, and in particular the insulating region 3 may be absent.

Furthermore, the epitaxial layer 2 may not be present, and the drain region 8 may be provided directly in the substrate 1.

Finally, the drain-contact region 17 and gate-contact region 19 may be made of a material different from silicide, for example metal.

Having thus described at least one illustrative embodiment of the invention, various alterations, modifications, and improvements will readily occur to those skilled in the art. Such alterations, modifications, and improvements are intended to be within the spirit and scope of the invention. Accordingly, the foregoing description is by way of example only and is not intended as limiting. The invention is limited only as defined in the following claims and the equivalents thereto.

What is claimed is:

1. An integrated device, comprising:
a first conductive region;
a second conductive region arranged at a distance from the first conductive region;
an etch-stop layer, made of a first dielectric material, at least partially overlapped on said first and second conductive regions;
an insulating layer, made of a second dielectric material, different from the first, overlapped on said first and second conductive regions and on said etch-stop layer; and
at least one through opening extending through said insulating layer and said etch-stop layer,
a barrier layer, made of a third dielectric material, different from the first, arranged between the first conductive region and the etch-stop layer and between the second conductive region and the etch-stop layer.

2. The device according to claim 1, comprising a switching device in MOS technology, wherein the first conductive region is a control terminal, and the second conductive region is a conduction terminal.

3. The device according to claim 1, further comprising a contact structure formed in said through opening, said contact structure comprising a layer of conductive material configured to electrically contact said second conduction region.

4. The device according to claim 1, wherein the etch-stop layer is made of silicon nitride or silicon oxynitride.

5. The device according claim 1, wherein the barrier layer is made of silicon oxide.

6. The device according to claim 1, wherein the barrier layer has a thickness of between 10 nm and 100 nm.

7. The device according to claim 2, comprising a semiconductor body, wherein said conduction terminal is formed inside the substrate, said control terminal is arranged above the semiconductor body, laterally and at a distance from the conduction terminal, and a dielectric insulating region extends between the control terminal and the conduction terminal.

8. A process for manufacturing a contact structure for an integrated device, comprising the steps of:
forming a first conductive region;
forming a second conductive region at a distance from the first conductive region;
forming, at least partially overlapped on said first and second conductive regions, an etch-stop layer, made of a first dielectric material;
forming an insulating layer, made of a second dielectric material different from the first, overlapped on said first and second conductive regions and on said etch-stop layer; and
removing selective portions of said insulating layer and of said etch-stop layer, to form at least one through opening,
wherein, before said step of forming the etch-stop layer, forming a barrier layer, made of a third dielectric material, different from the first.

9. The process according to claim 8, further comprising, immediately after said step of removal of selective portions of said insulating layer and of said etch-stop layer, the step of removal of a selective portion of said barrier layer.

10. The process according to claim 8, wherein the third dielectric material is silicon oxide of a thickness of between 10 nm and 100 nm.

11. The process according to claim 8, wherein the first dielectric material is made of silicon nitride or silicon oxynitride.

12. The process according to claim 8, further comprising the step of providing a semiconductor body; wherein forming a first conductive region comprises providing a control terminal of a switching device in MOS technology on the semiconductor body, and forming a second conductive region comprises forming a conduction terminal inside the semiconductor body, and the step of forming the barrier layer comprises depositing the third dielectric material on the semiconductor body.

13. The process according to claim 12, further comprising forming a dielectric insulating region in the semiconductor body between the control terminal and the conduction terminal.

14. The process according to claim 8, further comprising, after the step of forming at least one through opening, the step of depositing conductive material in said through opening so as to form a contact structure in direct electrical contact with said second conductive region.
